(19) United States
(12) Patent Application Publication
(10) Pub. No.: US 2002/0118845 A1
(43) Pub. Date: Aug. 29, 2002

(54) Enhancing source coding systems by adaptive transposition

(76) Inventors: Fredrik Henn, Bromma (SE); Kristofer Kjorling, Solna (SE); Per Ekstrand, Stockholm (SE); Lars Villemoes, Jarfalla (SE)

Correspondence Address: BIRCH STEWART KOLASCH & BIRCH, PO BOX 747, FALLS CHURCH, VA, 22040-0747, US

(21) Appl. No.: 10/022,526

(22) Filed: Dec. 20, 2001

(30) Foreign Application Priority Data
Dec. 22, 2000 (SE) 0004818-1

(51) Int. Cl. H03G 5/00; H04R 29/00

(52) U.S. Cl. 381/98; 381/56

(57) ABSTRACT

The present invention relates to a new method for enhancement of source coding systems using high-frequency reconstruction. The invention teaches that tonal signals can be classified as either pulse-train-like or non-pulse-train-like. Relying on this classification, significant improvements on the perceived audio quality can be obtained by adaptive switching of transposers. The invention shows that the so-switched transposers must have fundamental differences in their characteristics.

### TECHNICAL FIELD

The present invention relates to a new method for enhancement of source coding systems using high-frequency reconstruction. The invention teaches that tonal signals can be classified as either pulse-train-like or non-pulse-rain-like. Relying on this classification, significant improvements on the perceived audio quality can be obtained by adaptive switching of transposers The invention shows that the so-switched transposers must have fundamental differences in their characteristics.

### BACKGROUND OF INVENTION

In “Source Coding Enhancement using Spectral-Band Replication” [WO 98/57436], transposition was defined and established as an efficient means for high frequency generation to be used in a HFR (High Frequency Reconstruction) based codec. Several transposer implementations were described. Howeve apart from a brief discussion on transient response improvements, programme dependent adaptation of fundamental transposer characteristics was not elaborated upon

### SUMMARY OF THE INVENTION

The present invention teaches that tonal passages, i.e. excerpts dominated by contributions from pitches instruments, can be characterised as “pulse-train-like” or “non-pulse-train-like”. A typical example of former is the human voice in case of vowels, or a single pitched instrument, such as trumpet, where the “excitation signal” can be modelled as a “pulse-train”. The latter is the case where several different pitches are combined, and thus no single pulse-train can be identified. According to the present invention, the performance can be significantly improved, by discriminating between the above ti cases, and adapting the transposer properties correspondingly.

When a pulse-train-like passage is detected, the transposer shall preferably operate on a per-pulse basis Here, the decoded lowband, serving as the input signal to the transposer, can be viewed as a series of impulse responses h(n) of lowpass character with cut off frequency f_{c}, separated by a period Tₚ. This corresponds to a Fourier series with fundamental frequency 1/Tₚ, containing harmonics at all integer multiples of 1/Tₚ up to the frequency f_{c}. The objective of the transposer is to increase the bandwidth the individual responses h(n) up to the desired bandwidth Nf_{c} where N is the transposition factor, without altering the period A. Since the pulse period is preserved, the transposed signal still correspo to a Fourier series with fundamental 1/Tₚ, now containing all partials up to Nf_{c}. Hence this method provides a perfect continuation to the Vacated Fourier series of the lowband. Some prior art methods satisfy the requirement of preservation of the pulse period. Examples are frequency translation, and FD-transposition according to [WO 98/57436], where the window is selected short enough not to contain more than one period, i.e. length(window)≦Tₚ. Neither of those implementations handle material with multiple pitches well, and only the FD-Utsposition provides a perfect continuation to the truncated Fourier series of the lowband.

When a non-pulse-train-like passage is detected e.g. when multiple pitches are at hand, the demands on the transposer instead shifts from preservation of pulse periods to preservation of integer relationships between lowband harmonics and generated higher partials. This requirement is met by the FD-transposition methods in [WO 98/57436], where the window is selected long enough that many periods T of the individual pitches forming the sequence are contained within one window, i.e. length(window)>>Tᵢ. Hereby any truncated Fourier series [fᵢ, 2fᵢ, 3fᵢ, . . . ] in the transposer source frequency range is transposed to [Nfᵢ, 2 Nfᵢ, 3 Nfᵢ, . . . ], where N is the integer transposition factor. Clearly, as opposed to the above per-pulse operation, his scheme does not generate a full continuation of the lowband Fourie series. This is tolerable for multi pitched signals, but not ideal for the single pitch pulse-train-like case. Thus, this transposition mode is preferably only used in non-pulse-train-like cases,

According to the present invention, discrimination between pulse-like and non-pulse-like signals can be performed in the encoder, and a corresponding control signal sent to the decoder. Alternatively, the detection can be done in the decoder, eliminating the need for control signals but at an expense of higher decoder complexity. Examples of detector principles arc transient detection in the time domain, as well as peak-picking in the frequency domain. The decoder includes means for the necessary transposer adaptation. As an example, a system using frequency translation for the pulse-train-like case, and a long window FD transposer for the non-pulse train-like case, is described. The actual switching or cross fading between transposers is preferably performed in an envelope-adjusting filterbank.

The present invention comprises the following features:

Adaptively over time selecting different methods for high frequency generation, based on whether the signal being processed has a pulse-train-like character or a non-pulse-train-like character

the selection is done based on analysis by peak-picking in a time- and frequency-domain representation of the signal.

the different methods for high frequency generation are frequency translation and FD transposition, or

the different methods for high frequency generation are FD transposition with different window size or

the different methods for high frequency generation are time-domain pulse train transposition and FT transposition.

### BRIEF DESCRIPTION OF THE DRAWINGS

The present invention will now be described by way of illustrative examples, not limiting the scope or spirit of the invention, with reference to the accompanying drawings, in which.

FIG. 1a illustrates an input pulse-train signal x(n).

FIG. 1b illustrates the magnitude spectrum |X(f)| of the signal x(n).

FIG. 2a illustrates the impulse response h₀(n) of a FIR filter.

FIG. 2b illustrates file magnitude spectrum |H₀(f)| of the FIR filter.

FIG. 3a illustrates a signal Y₀(n)=x(n)h₀(n).

FIG. 3b illustrates the magnitude spectrum |Y₀(f)| of the signal y₀(n).

FIG. 4a illustrates the decimated impulse response h₁(n) of a FIR filter

FIG. 4b illustrates the magnitude spectrum |H₁(f)| of the decimated FIR filter.

FIG. 5a illustrates the transposed signal y₁(n).

FIG. 5b illustrates the magnitude spectrum |Y₁(gf)| of the signal y₁(n).

FIG. 6 illustrates the magnitude spectrum |Y₂(f)| after FD-transposition with a long window of th signal x(n).

FIG. 7 illustrates an implementation of the present invention on the decoder side.

### DESCRIPTION OF PREFERRED EMBODIMENTS

The below-described embodiments are merely illustrative for the principles of the present invention for adaptive transposer switching for HER systems. It is understood that modifications and variations of the arrangements and the details described herein will be apparent to others skilled in the art. It is the intent therefore, to be limited only by the scope of the impending patent claims and not by the specific details presented by way of description and explanation of the embodiments herein.

“Ideal transposition” of a single pitched pulse-train-like signal can be defied by means of a simple model. Let the original signal be a sum of diracs δ(n), separated by m samples, i.e. a pulse-train

$$x ( n ) = {\sum }_{l = - ∞}^{∞} δ ( n - l m ) \qquad ( Eq . 1 )$$

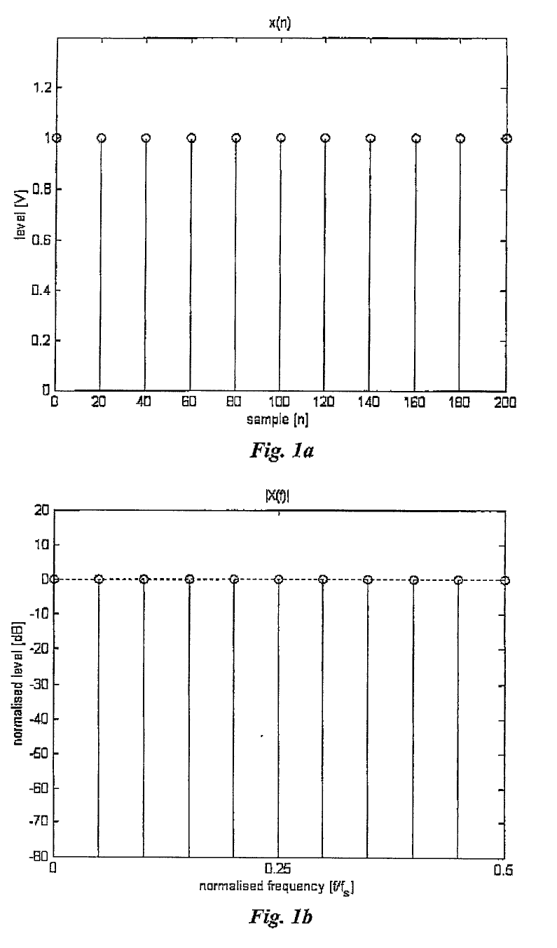

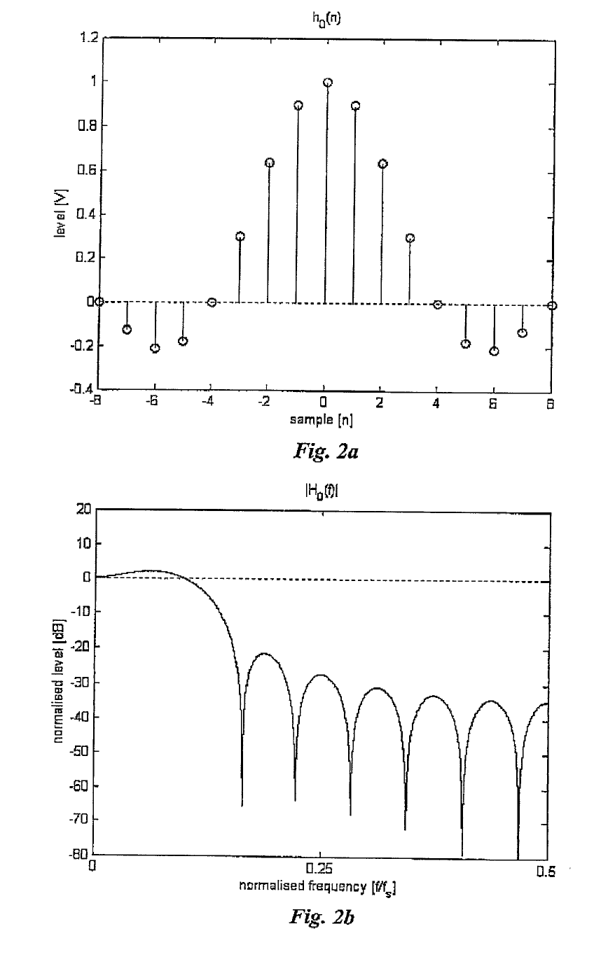

FIG. 1a shows x(n), and FIG. 1b the corresponding magnitude spectrum |X(f)|. Clearly |X(f)| corresponds to a of a Fourier series with fundamental fₛ/m, where fₛ is the sampling frequency. Let y(n be a low-pass filtered version of x(n), where the low-pass FIR filter has the impulse response h₀(n) of lengthp such that p<m, see FIGS. 2a and 2b for the time and frequency domain representation respectively. The filter cut-off frequency is f_{c}. The output signal is then given by

$${y}_{0} ( n ) = x ( n ) * {h}_{0} ( n ) = {\sum }_{l = - ∞}^{∞} δ ( n - l m ) * {h}_{0} ( n ) = {\sum }_{l = - ∞}^{∞} {h}_{0} ( n - l m ) \qquad ( Eq . 2 )$$

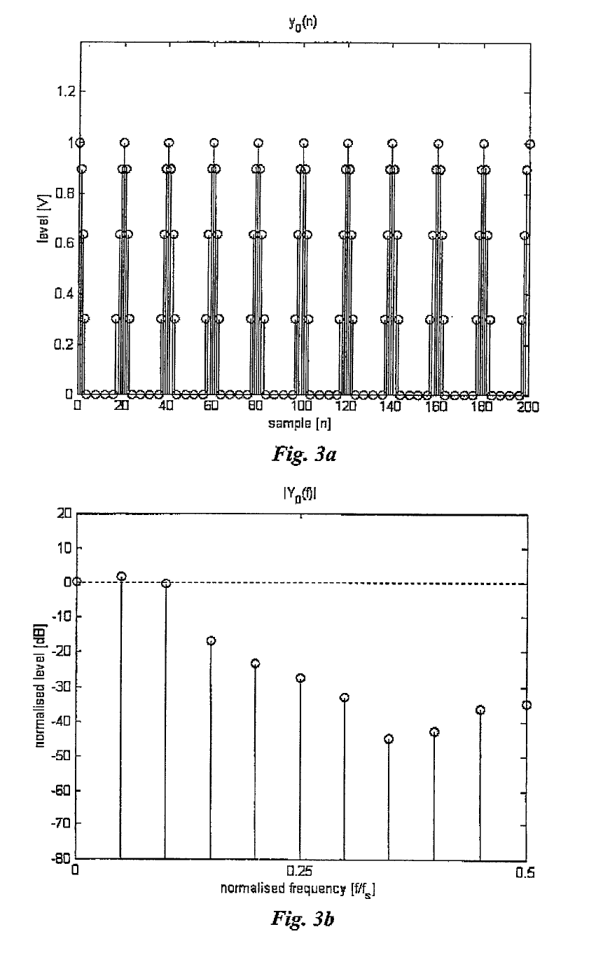

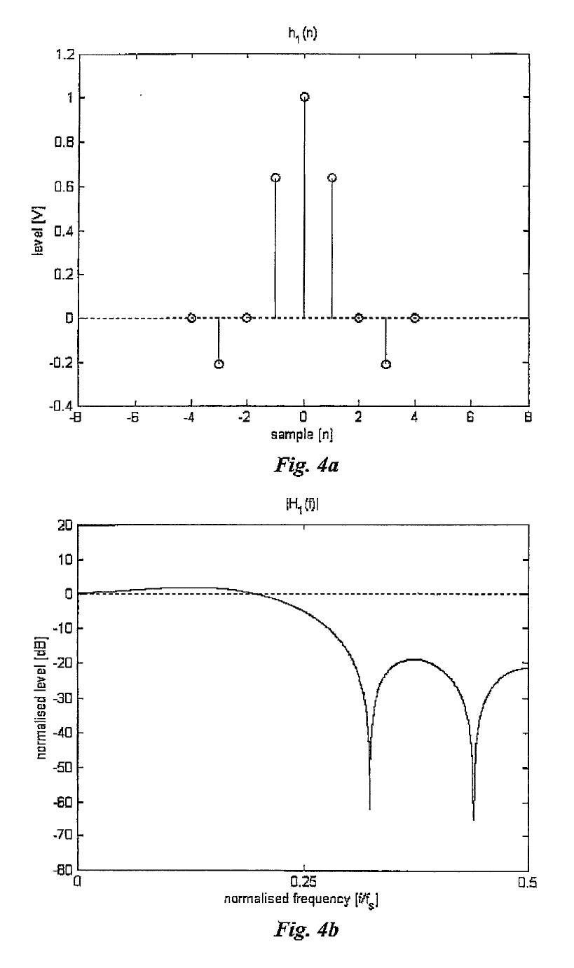

i.e. a series of impulse responses, separated by n samples. FIGS. 3a and 3b show y₀(n) and Y₀(f)|. The original Fourier series has effectively been truncated at the frequency f_{c}. Assume that a time domain based transposer is able to detect the individual impulse responses h₀(n−1m), and that those signals art decimrated by a factor 2, i.e. every second sample is fed to the output. The discarded samples are compensated for by insertion of zeroes between the shorter responses h₁(n−1m), in order to preserve it length of the signal. The decimated impulse response h₁(n) and the corresponding frequency representation |H₁(f)| are shown in FIGS. 4a and 4b. Obviously, the narrowing of the time domain signal corresponds to a widening of the frequency domain signal, in his case by a factor 2. Finally, the transposed signal

$${y}_{1} ( n ) = {\sum }_{l = - ∞}^{∞} {h}_{1} ( n - l m )$$

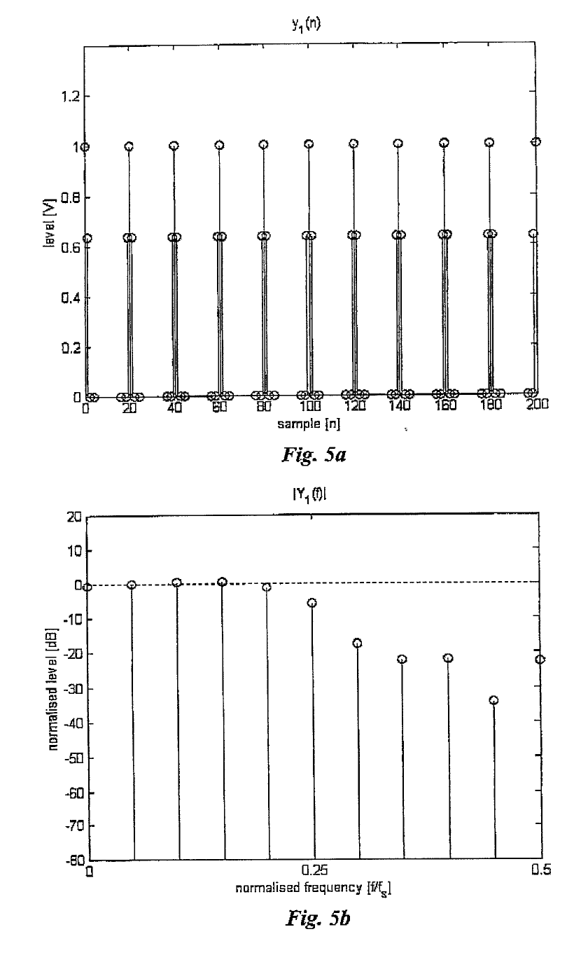

and |Y₁(f)| is shown if FIGS. 5a and 5b. The bandwidth o the LP filtered pulse-train has been increased, while pressing the correct time and thereby also frequency, properties. The output signal y₁(n) corresponds to a Fouier series with partials reaching u to the frequency 2f_{c}.

The above transposition can be approximated in several ways. One approach is to use a frequency doma transposer (FD-transposer) such as the SIFT transposer described in [WO 98/57436], but with different window sizes, i.e. a short window is used for pulse-train signals, and a long window is used for all other signals. The short window (of length ≦m in the above example) ensures that the transposer operates on per pulse basis, giving the desired pulse transposition outlined above. A different approach for pulse transposition is using single-side-band modulation. This ensures that the period time between the pulses Tₚ is correct, however, the generated partials are not harmonically related to the partials of the lowband. It should also be pointed out that different pulse-train transposition algorithms may perform differently for different program material. Therefore several pulse-train transposers could be used with suitable detection algorithms, in the encoder and/or the decoder, to ensure optimal performance.

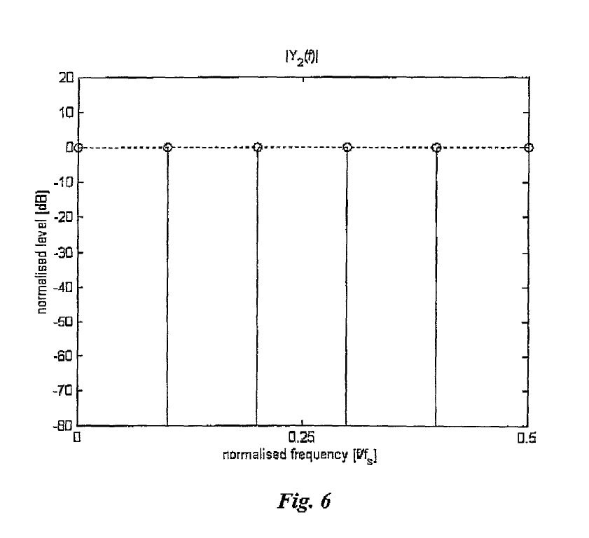

For the pulse-train signal used in the example above, an implementation with a FD-transposition method using a long window will give unsatisfactory results. This is due to the following: When using a long window (of length>>m) in the FD-transposition method, the following relation applies:

$$u ( n ) = {\sum }_{i = 0}^{N - 1} {e}_{i} ( n ) cos ( 2 π {f}_{i} n / {f}_{s} + {α}_{i} ) \to v ( n ) = {\sum }_{i = 0}^{N - 1} {e}_{i} ( n ) cos ( 2 π M {f}_{i} n / {f}_{s} + {β}_{i} ) , \qquad ( Eq . 3 )$$

where u(n) is the input, v(n)is the output, M is the transposition factor, N is the number of sinusoids, eᵢ(n), αᵢ are the individual input frequencies, time envelopes and phase constants respectively, βᵢ are tl arbitrary output phase constants and fₛ is the sampling frequency, and 0≦Mfᵢ≦fₛ/2. The input signal x(n) will using the relation in Eq. 3 yield an output signal y₂.(n) with a magnitude spectrum y₂(f) according to FIG. 6, where the partials of Y₂ (n) are harmonically related to the partials of x(n). Howeve the distance between them has increased according to the transposition factor, i.e. the pitch of the signal has increased by the transposition factor. When adding this new highband signal to the original lowban signal, the two different pitches can clearly be discriminated. This causes for instance speech signals to sound as if an additional speaker was speaking simultaneously but at a higher pitch, i.e. a so called gho voice occurs.

However, as soon as the input signal does not display single-pitched pulse-train characteristics, a pulse transposition is not applicable if high-quality HFR is required. Thus it is highly desirable to detect whic transposition method that gives the best result at a given time, in order to optimise performance of the IBM system.

In order to benefit from the different transposition characteristics in a decoder it is necessary to, in the encoder and/or the decoder, asses which transposition method will give the best results at a given time. There are several ways to detect pulse-train-like characteristics in a signal, it can be done in either the time-domain or in the frequency domain. If a pulse train has a period time Tp the pulses will be separa in time by that period time and the frequency components will be 1/Tₚ apart. Hence if Tₚ is high, i.e. a low-pitched pulse-train, this is preferably detected in the time domain since the pulses are relatively far apart and thus easy to discriminate. However, if Tₚ is low, this corresponds to a high-pitched pulse-train and hence it is more easily detected in the frequency domain For time domain detection it is preferable t spectrally whiten the signal in order to obtain an as pulse train like character as possible for easier detection. The detection schemes in the time domain and the frequency domain are solar. They are based on peak picking and statistical analysis of the distances between picked peaks. In the time domain the peak-picking is done by comparing the energy and peak level of the signal before and after an arbitrary point, thus searching for transient behaviour in the signal. In the frequency domain the peak detection is done on the harmonic product spectrum, which is a good indication if a strong harmonic series is present The distances between the detected pitches are presented in a histogram upon which the detection is made by comparing the ratio between pitch-related entries and non-pitch related entries.

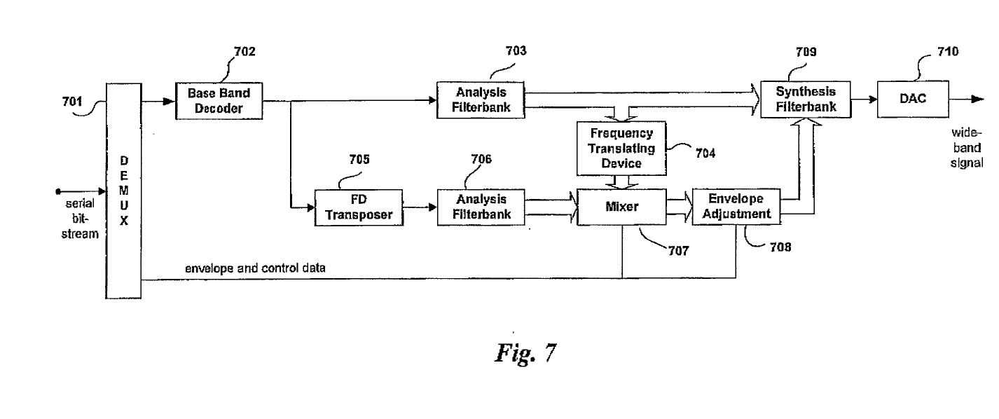

The implementation exemplified in FIG. 7 shows the usage of two different types of transposition metho in the same decoder system—the types being a FD transposer using a long window and a frequency translating device [PCT/SE01/01150]. The demultiplexer 701 unpacks the bitstream signal and feeds it t an arbitrary baseband decoder 702. The output from the baseband decoder, i.e. a bandwidth-limited audi signal, is fed to an analysis filterbank 703, which splits the audio signal into spectral bands. The audio signal is simultaneously fed to an FD-transposer unit 705. The output therefrom is fed to an additional analysis filterbank 706, which is of the same type as the filterbank unit 703. The data from the filterbank unit 703 is patched 704 according to the principles of frequency translating devices and fed to the mixin unit 707 together with the output from the analysis filterbank 706. The mixing unit blends the data according to the control signal transmitted from the encoder or control signals obtained by the decoder. The blended spectral data is subsequently envelope adjusted in the envelope adjuster 708, using data anc control signals sent in the bistream The spectral-adjusted signal and the data from the analysis filterban 703 are fed to a synthesis filterbank unit 709, thus creating an envelope adjusted wideband signal. Finall the digital wideband signal is converted 710 to an analogue output signal.

1. A method for enhancement of audio source coding systems using high frequency reconstruction, characterised by:
adaptively over time selecting different methods for high frequency generation, based on whether the signal being processed has a pulse-train-like character or a non-pulse-train-like character

2. A method according to claim 1, characterised in that said selection is done based on analysis by peas picking in a time- and frequency-domain representation of said signal.

3. A method according to claim 1, characterised in that said different methods for high frequency generation are frequency translation and ED transposition.

4. A method according to claim 1, characteiised in that said different methods for high frequency generation are FD transposition wit different window sizes.

5. A method according to claim 1, characterised in that said different methods for high frequency generation are time-domain pulse train transposition and D transposition.
